(19) United States
(12) Patent Application Publication
(10) Pub. No.: US 2026/0052998 A1
(43) Pub. Date: Feb. 19, 2026

(54) IN-MODULE SHIELDING

(71) Applicant: SKYWORKS SOLUTIONS, INC., Irvine, CA (US)

(72) Inventor: David Richard Pehlke, Westlake Village, CA (US)

(21) Appl. No.: 19/279,835

(22) Filed: Jul. 24, 2025

Related U.S. Application Data
(60) Provisional application No. 63/669,786, filed on Jul. 11, 2024.

(51) Int. Cl. H01L 23/552; H01L 23/498; H01L 23/538; H05K 1/02

(52) U.S. Cl. CPC H01L 23/552; H01L 23/5385; H01L 23/5389; H05K 1/0224; H01L 23/49816; H05K 2201/042; H05K 2201/0723

(57) ABSTRACT

A device may include a set of two or more layers including printed circuit boards (PCBs). A device may include a first recess formed within the set of two or more layers.

### RELATED APPLICATION

This application claims priority to U.S. Provisional Application No. 63/669,786, filed Jul. 11, 2024, and entitled IN-MODULE SHIELDING, the disclosure of which is hereby incorporated by reference in its entirety.

### BACKGROUND

### Field

The present disclosure generally relates to the field electronic assemblies, and more particularly, to shielding of components within an electronic assembly.

### Description of Related Art

In multi-chip modules (MCMs), shielding can be used to prevent and/or minimize interference between transmitting and/or receiving components. In some cases, overmold sputtered and/or deposited conductive shields can be designed to enclose the entire overmolded package to effect electromagnetic isolation with external components and the victims and/or aggressors outside the module package.

### SUMMARY

In some implementations, the present disclosure relates to a multi-chip module including a set of two or more layers including printed circuit boards (PCBs) and a first recess formed within the set of two or more layers.

In some aspects, the techniques described herein relate to a multi-chip module, further including an overmold layer extending over the first recess. In some aspects, the techniques described herein relate to a multi-chip module, further including a second recess formed within the set of two or more layers.

In some aspects, the techniques described herein relate to a multi-chip module, further including one or more conductive pads extending through the set of two or more layers. In some aspects, the techniques described herein relate to a multi-chip module, further including two or more conductive vias disposed on either side of the first recess and configured to electrically isolate the first recess.

Some implementations of the present disclosure relate to a multi-chip module including a first set of two or more layers including printed circuit boards (PCBs), a second set of two or more layers including PCBs, and a first recess formed between the first set and the second set.

In some aspects, the techniques described herein relate to a multi-chip module, further including one or more solder bumps interconnecting the first set and the second set. In some aspects, the techniques described herein relate to a multi-chip module, further including a first fence attached to the first set and enclosing the first recess.

In some aspects, the techniques described herein relate to a multi-chip module, further including a second fence attached to the second set and enclosing the first recess. In some aspects, the techniques described herein relate to a multi-chip module, wherein the first recess is configured to electrically isolate the first recess.

In some aspects, the techniques described herein relate to a multi-chip module, further including a second recess formed between the first set and the second set. In some aspects, the techniques described herein relate to a multi-chip module, further including a third set of two or more layers including PCBs and a second recess formed between the second set and the third set.

In accordance with some implementations, the techniques described herein relate to a module including a first set of layers including printed circuit boards (PCBs) a second set layers including PCBs, and a first recess formed between the first set and the second set.

In some aspects, the techniques described herein relate to a module, further including one or more solder bumps interconnecting the first set and the second set. In some aspects, the techniques described herein relate to a module, further including a first fence attached to the first set and enclosing the first recess.

In some aspects, the techniques described herein relate to a module, further including a second fence attached to the second set and enclosing the first recess. In some aspects, the techniques described herein relate to a module, wherein the first recess is configured to electrically isolate the first recess.

In some aspects, the techniques described herein relate to a module, further including a second recess formed between the first set and the second set. In some aspects, the techniques described herein relate to a module, further including a third set of two or more layers including PCBs and a second recess formed between the second set and the third set.

In some aspects, the techniques described herein relate to a module, further including a second set of one or more solder bumps interconnecting the second set and the third set.

### BRIEF DESCRIPTION OF THE DRAWINGS

Various embodiments are depicted in the accompanying drawings for illustrative purposes, and should in no way be interpreted as limiting the scope of the inventions. In addition, various features of different disclosed embodiments can be combined to form additional embodiments, which are part of this disclosure. Throughout the drawings, reference numbers may be reused to indicate correspondence between reference elements.

FIG. 1 illustrates a printed circuit board (PCB) stack in accordance with one or more examples.

FIG. 2 illustrates another example multi-chip module (MCM) stack in accordance with one or more examples.

FIG. 3 illustrates another example MCM stack in accordance with one or more examples.

FIG. 4 illustrates a module including front-end configurations.

### DESCRIPTION

The headings provided herein, if any, are for convenience only and do not necessarily affect the scope or meaning of the claimed invention.

### Overview

In multi-chip modules (MCMs), shielding can be used to prevent and/or minimize interference between transmitting and/or receiving components. In some cases, overmold sputtered and/or deposited conductive shields can be designed to enclose the entire overmolded package to effect electromagnetic isolation with external components and the victims (i.e., receivers) and/or aggressors (i.e., transmitters) outside the module package. Additionally or alternatively, an MCM may be designed with various in-module compartmentalized dividers to build conductive and/or grounded walls to separate the victims and/or aggressors within the module from interfering with one another.

In-module conductive walls and/or fences may comprise various bondwire configurations of loops and/or vertical posts that can connect the MCM top-side ground with the upper conductive shield coated atop the upper surface of the mold compound and/or through the conductive bondwire. An exposed portion of the bondwire above the package top can be lapped and/or grinded down to a planar conformal top surface at the target package height. There may exist challenges in which these partially conductive and/or relatively less dense systems may not provide desirable isolation between the compartments of the module (e.g., in the range of approximately 10 dB).

Described herein are various systems and/or methods of shielding components of MCMs. In some examples, an MCM may comprise one or more recessed regions in an upper surface of a stack comprising MCM, laminate, and/or FR4 components. In such examples, an active die (e.g., a flip-chip mounted with bumps and/or bondwire topside die connection), Surface-mount technology components (SMTs), and/or one or more filter dies may be soldered and attached to the upper surface and/or other region of the stack. A Solder mask of an inner MCM metal layer may be prepared differently from other non-bondable inner metal layers to facilitate attachment of one or more dies and/or bond/flip-chip mounting. The stack may comprise solid and/or highly conductive vias forming a via fence and/or wall to enable a highly conductive and/or reliable ground to surround one or more active circuits and/or result in effective isolation between integrated aggressor and/or victims within the single module. The conductive vias can include any electrical connections extending between multiple layers of an MCM stack of layers. A via can comprise a hole drilled through the layers and filled and/or plated with metal to form an electrical connection through insulating and/or laminate layers of the stack.

Examples described herein can advantageously provide fence(s) and/or wall(s) within a printed circuit board (PCB) and/or MCM to form a Faraday cage around various transmitting, receiving, and/or passive components. The fence(s) and/or wall(s) can be soldered down to eliminate any air gaps. Examples provided herein advantageously leverage structure of an existing PCB to effectively provide shielding at the PCB without requiring additional and/or external structures. In some cases, PCBs may be dual-sided. Similarly, fences and/or walls described herein can advantageously be disposed at both and/or either side of PCBs to provided shielding at both and/or either side.

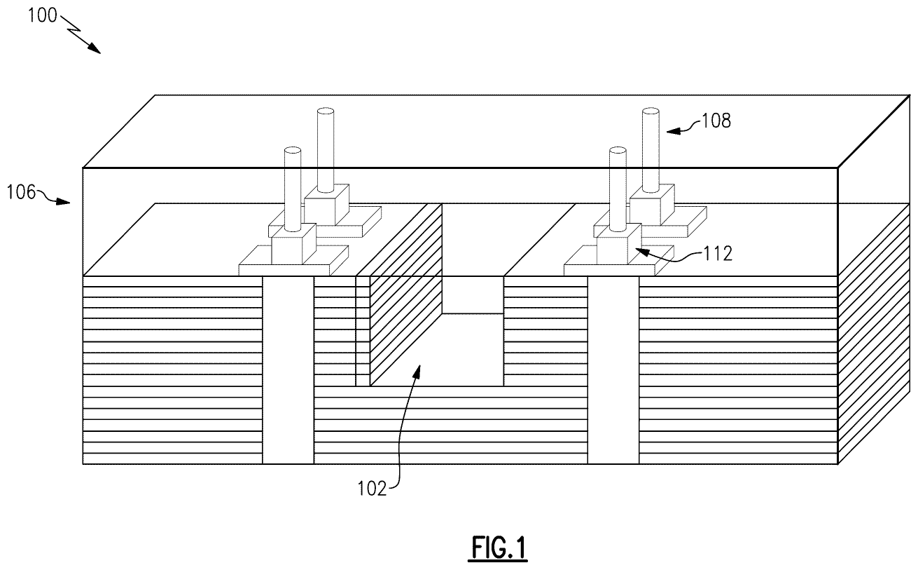

FIG. 1 illustrates a PCB stack 100 in accordance with one or more examples. The stack 100 may comprise a recess 102 and/or recessed tub configured to receive and/or shield one or more active and/or passive circuits (e.g., dies, filters, SMT devices, etc.). The recess 102 may be etched out of a stack of vias and/or PCBs.

The stack 100 may comprise an overmold layer 106 and/or substrate composed of any suitable material (e.g., resin and/or thermoplastic elastomer (TPE)). In some examples, the stack 100 may comprise one or more conductive pads 108, which may be stitch-bonded to extend through layers of PCBs, substrates, and/or other materials. The one or more conductive pads 108 may connect with and/or extend at least partially through the overmold layer 106.

In some examples, the stack 100 may comprise one or more highly conductive vias 112 disposed around and/or adjacent to the recess 102. The vias 112 may be configured to form a tight and/or closely-spaced fence to enclose the components disposed within the recess 102.

Components placed within the recess 102 can be relatively thin and/or can be ground down to a relatively thin profile (e.g., approximately 100 microns or less). Ball bumps may be used to mount the components to the stack 100 and/or within the recess 102. In some examples, contact pads and/or solder balls may additionally or alternatively be used to mount components to the stack 100. Ball bumps may be relatively thicker than silicon dies and/or other components of the stack 100.

In some examples, the stack 100 may comprise pins (e.g., at least at an outside and/or bottom of the stack 100). The recess 102 may provide space for dies and/or solder balls. The stack 100 may comprise an acoustic filter die, which may include a heterojunction bipolar transistor (HBT) power amplifier die. A complementary metal-oxide semiconductor (CMOS) controller may be mounted on the HBT die.

The recess 102 may allow for dual-sided mounting of various components within the stack 100 to advantageously reduce size requirements of the stack 100 and/or associated systems. The stack 100 may have any suitable number of layers. In some examples, the stack 100 may be coreless.

In some examples, the stack 100 may comprise conductive vias 112 extending through layers of the stack 100. The stack 100 may comprise various bonding components configured to reach up to the overmold layer 106. The overmold layer 106 may comprise a conductive layer on top of the stack 100 and so on.

The recess 102 may be formed in the stack 100 while maintaining structural integrity of the stack 100. In some cases, thinning the stack 100 too much may present mechanical challenges. The stack 100 may require sufficient structure to maintain structural integrity. In some examples, inclusion of the recess 102 may allow for reducing a height of the stack 100, as components otherwise disposed along a top and/or bottom of the stack 100 may be disposed within the recess 102.

In some examples, the recess 102 may be sufficiently large to receive SMT components, which may be relatively taller than other components of the stack 100. For example, SMT components may comprise coils and/or inductors. A quality (Q) factor of a coil may be heavily dependent on a geometry of the coil. Larger coils and/or larger volumes of inductive coils can be associated with lower parasitic and/or better mutual coupling and/or higher Q. As a result, coils can generally increase a size of a stack 100. However, the recess 102 may advantageously allow for inclusion and shielding of relatively large coils and/or other components without unnecessarily increasing a profile of the stack 100.

The stack may comprise conductive bottom and/or layers and/or conductive fences and/or walls around and/or within the recess 102 (i.e., pit). Ground may be extended up to the overmold using a bottom wire technology.

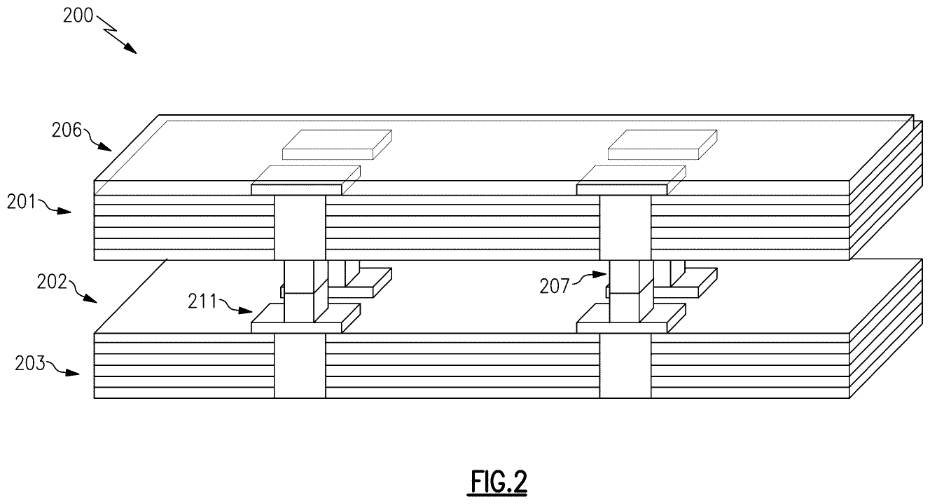

FIG. 2 illustrates another example MCM stack 200 in accordance with one or more examples. The stack 200 may comprise a first PCB 201 and/or a second PCB 203 with a recess 202 disposed between the first PCB 201 and the second PCB 203. The recess 202 may be sandwiched between the first PCB 201 and the second PCB 203. The recess 202 may be configured to receive and/or shield various active and/or passive components of the stack 200. The stack 200 may comprise one or more bumps 207 interconnecting the first PCB 201 and the second PCB 203. In some examples, one or more active and/or passive components (e.g., SMT devices) may be mounted to the first PCB 201 and/or to the second PCB 203. The active and/or passive components may only be mounted to one of the surfaces (e.g., only to the first PCB 201 or only to the second PCB 203).

The stack 200 may include additional recesses 202, including one or more recesses 202 cut and/or etched into layers of the stack 200, as in the example of FIG. 1. Similarly, the example of FIG. 1 may additionally include sandwiched recesses 202 as shown in FIG. 2.

The bumps 207 may be aligned through and/or between the first PCB 201 and/or the second PCB 203. The first PCB 201 and/or second PCB 203 can comprise laminate layers to which the bumps 207 may be mounted. The recess 202 may comprise a gap between laminates of the first PCB 201 and the second PCB 203. In some examples, the bumps 207 may be configured to provide fencing and/or shielding for components placed within the recess 202 and/or may provide an electrical connection for grounding and/or signals. One or more dies, SMT components, and/or other devices may be placed in the recess 202 between the first PCB 201 (e.g., first MCM) and/or second PCB (e.g., second MCM). The recess 202 and/or components within the recess 202 may be surrounded with one or more shield walls and/or heavy ground.

The bumps 207 may comprise a wire bond extending from the ground on the stack 200 up to an overmold layer 206 (e.g., conductive sputter overlayer) at a top portion of the stack 200. In some examples, the stack 200 may comprise one or more exposed conductive stripes extending through and/or between the first PCB 201 and/or second PCB 203 in place of and/or in addition to the bumps 207. The bumps 207 and/or stripes may be stacked on other metals to form a solid wall within the stack 200. In some examples, outside portions of the solid wall may be etched to make more room for additional active and/or passive devices (e.g., chips). The stack 200 may advantageously have multiple surfaces for placing devices, including on top of the stack (e.g., at the overmold layer 206), on a bottom of the stack 200, and/or between portions of the stack 200. While only a single recess 202 is shown in FIG. 2, additional recesses may be placed between portions of the stack 200.

In some examples, the bumps 207 and/or stripes may comprise distinct balls and/or elements mounted together. However, the bumps 207 and/or stripes may additionally or alternatively be continuous without any gaps between portions of the bumps 207 and/or stripes. Accordingly, the stack 200 may comprise one or more continuous walls of conducive metal.

The first PCB 201 and/or second PCB 203 may serve as interposers providing electrical connection between multiple elements. The first PCB 201 and/or second PCB 203 may have multiple layers such that metal traces can run around and/or through the stack 200 to establish signal connectivity.

The stack 200 may comprise bond pads 211 coupled to the bumps 207. In some examples, the stack 200 may comprise solder protection including the bond pads 211 and/or overmold layer 206. The overmold layer 206 may comprise resin, epoxy, and/or other material configured to provide insulation by not allowing metals to make contact with the stack 200 below the overmold layer 206. In some examples, the overmold layer 206 may comprise holes to allow access to the metal below the overmold layer 206. The bond pads 211 may be configured to receive solder bond footprints of active and/or passive components (e.g., SMT devices, dies, etc.) to be able to make connections. Solder may be applied through holes of the overmold layer 206 and/or other access points to create connections throughout the stack 200.

Sides of the recess 202 may be closed to prevent moisture and/or temperature from leaking into the components of the stack 200 (e.g., semiconductor dies and/or other components that can delaminate when moisture and temperature are applied). In some examples, dies can be placed and/or assembled with solder bumps and/or other features to make connections to the first PCB 201 and/or second PCB 203.

In some examples, the recess 202 may be entirely and/or at least partially enclosed to increase shielding and/or passivation of the components within the recess 202. The stack 200 may comprise a trace and/or stripe all the way around with the recess 202 formed between portions of the stack 200. In some examples, the recess 202 may comprise one or more raised walls around edges of the first PCB 201 and/or second PCB 203. The raised walls may be soldered and/or assembled together to form a continuous wall and/or continuous solder connecting the portions of the stack 200 all the way around.

In some cases, the stack 200 may comprise some relatively sensitive components (e.g., victims, SMT devices, coils, etc.) on semiconductor dies. For example, the stack 200 may comprise antennas and/or current may be run through an inductor to generate a magnetic field. The magnetic field may extend beyond the components themselves and/or can radiate away from the stack 200. Whatever signal frequency and/or modulation may be running through a component (e.g., inductor) may radiate through the electromagnetic fields around the component.

Capacitive coupling may fall away rapidly with distance and/or may have a lower density. Accordingly, magnetic coupling may be of greater concern in terms of shielding.

In some examples, the stack 200 may comprise a tub (i.e., recess) on an upper portion of the second PCB 203 and/or on a lower side of the first PCB 201. Portions of the stack 200 may be assembled together to effectively build a metal coffin for placing sensitive components. For components within the recess 202, there may be some resonances. For example, the recess 202 may have a given geometry. At certain wavelengths, reflections of signals that bounce off walls of the recess 202 can form periodic and/or coherent types of cavities.

Receiver circuits can be naturally sensitive to noise and/or channel. Noise and/or spurious signals can pass through a filter path and/or can cause contamination. A receive sensitivity may be a minimum detectable signal that can be received with an acceptable signal-to-noise ratio while maintaining a good integrity as the signal is demodulated. As noise is layered over on top of a desired signal, the signal may be lost and/or may be difficult to read.

In some examples, a duplexer filter may be used to separate out transmission and receiving signals. Bandpass filters with different bandpass frequency ranges may be assembled together to provide strong isolation between the transmission part and the receiving part. The transmission filter and/or receiving filter may be brought together at an antenna port where they may share a common trace. On the common trace, transmit energy and/or signals may be sent out at the antenna and/or simultaneously a receive signal may be received. The filter may be configured to perform the splitting on a frequency basis. For example, the transmission frequencies can pass through the transmission side of the filter and/or the receive frequencies can pass through the receive side of the filter. Transmitters may be referred to herein as “aggressors” and/or receivers may be referred to herein as “victims.” The overmold layer 206 may be configured to convey and/or establish an electrical connection from ground to a top portion of the stack 200. The stack 200 may comprise a conductive layer sputtered on top of the overmold layer 206. The overmold layer 206 may be configured to provide improved structural integrity to the stack 200. In some examples, the overmold layer 206 may be cured through a heated process to solidify the overmold layer 206 (e.g., solidify epoxy and/or materials of the overmold layer 206). Moreover, the overmold layer 206 may be configured to protect against moisture entering into the components of the stack 200.

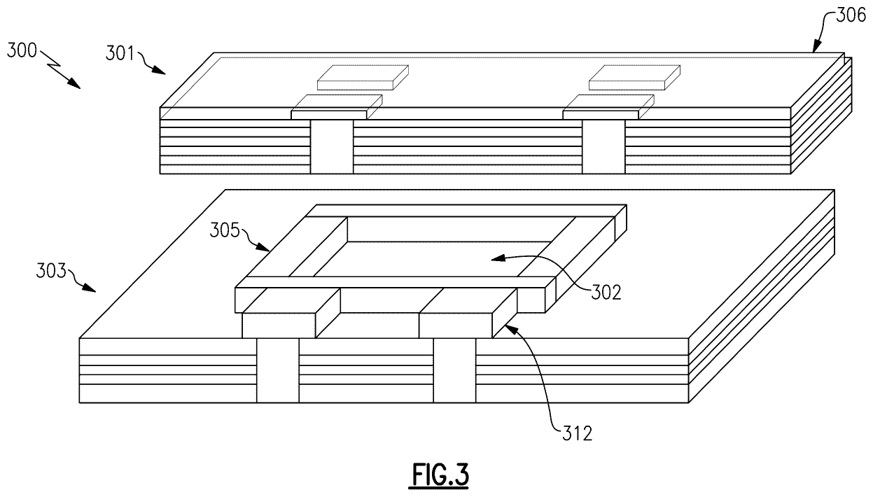

FIG. 3 illustrates another example MCM stack 300 in accordance with one or more examples. The stack 300 may comprise a recess 302 and/or tub formed within a fence 305 and/or wall. The fence 305 may comprise a pattern of relatively thick and/or trace metals placed within the laminate stack 300. The fence 305 may be connected to ground and/or the stack 300 may comprise solder (e.g., solder bumps) configured to connect a first portion 301 (e.g., set of PCBs and/or laminates) and/or a second portion 303 of the stack 300. In some examples, the fence 305 may be coupled to only one of the first portion 301 and/or the second portion 303. However, the fence 305 may be coupled to both the first portion 301 and the second portion 303. The stack 300 may comprise an overmold layer 306 at an upper portion of the stack 300.

The recess 302 may have any suitable size and/or shape. In some examples, the recess 302 may have a rectangular shape. The recess 302 may have a smaller surface area than layers of the first portion 301 and/or second portion 303. For example, the recess 302 may not cover an entire surface area of the first portion 301 and/or second portion 303.

In some examples, the recess 302 may be disposed centrally within the stack 300. For example, the recess 302 may be centrally positioned along a first axis and/or along a second axis of the stack 300. The recess 302 may be disposed between conductive vias 312 of the stack 300.

One or more laminate layers of the stack 300 may be removed to create the recess 302 and/or surrounding space. For example, laminate layers may be removed to create empty space to form the recess 302. The fence 305 may be formed and/or patterned on the first portion 301 or second portion 303 and/or may be attached to the first portion 301 and/or second portion 303 via solder connections.

In some examples, the stack 300 may comprise multiple fences 305. For example, a first fence 305 may be formed on the first portion 301 and/or a second fence 305 may be formed on the second portion 303. The first fence 305 may be attached to the second fence 305.

The stack 300 may comprise any number of portions and/or recesses 302. For example, the stack 300 may comprise the first portion 301, the second portion 303, and/or a third portion. The stack may comprise a second recess 302 disposed between the second portion 303 and the third portion. In some examples, the stack 300 may comprise multiple recesses 302 adjacent to each other. For example, the stack 300 may comprise a second recess 302 adjacent to the recess 302 shown in FIG. 3 and/or disposed between the first portion 301 and the second portion 303.

### Examples of Products and Architectures

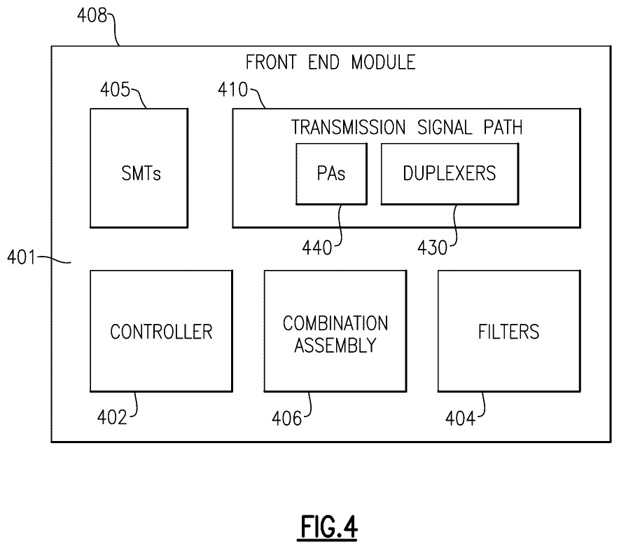

FIG. 4 illustrates that, in some embodiments, some or all of the front-end configurations can be implemented, wholly or partially, in a module. Such a module can be, for example, a front-end module (FEM). Such a module can be, for example, a diversity receiver (DRx) FEM. Such a module can be, for example, a multi-input, multi-output (MiMo) module.

In the example of FIG. 4, a module 408 can include a packaging substrate 401, and a number of components can be mounted on such a packaging substrate 401. For example, a controller 402 (which may include a front-end power management integrated circuit [FE-PIMC]), a combination assembly 406, a transmission signal path 410 that includes one or more duplexers 430 and one or more amplifiers 440 (e.g., PAs), the one or more amplifiers 440 being configured as described herein to utilize a hybrid quarter-wave impedance inverter to improve performance. A filter bank 404 (which may include one or more multiplexers) can be mounted and/or implemented on and/or within the packaging substrate 401. Other components, such as a number of SMT devices 405, can also be mounted on the packaging substrate 401. Although all of the various components are depicted as being laid out on the packaging substrate 401, it will be understood that some component(s) can be implemented over other component(s).

In some embodiments, the transmission signal path 410 can be implemented on a semiconductor die that is in turn mounted on the packaging substrate 401. In further embodiments, the duplexers 430 and/or the PAs 440 can be implemented on a single semiconductor die that is mounted on the packaging substrate 401. In various embodiments, one or more of the plurality of duplexers 430 or the PAs 440 are implemented on a semiconductor die with one or more of the other components mounted on a separate semiconductor die or on the packaging substrate 401.

### Terminology and Additional Embodiments

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general-purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general-purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid-state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions, and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A multi-chip module comprising:
a set of two or more layers including printed circuit boards (PCBs); and
a first recess formed within the set of two or more layers.

2. The multi-chip module of claim 1, further comprising an overmold layer extending over the first recess.

3. The multi-chip module of claim 1, further comprising a second recess formed within the set of two or more layers.

4. The multi-chip module of claim 1, further comprising one or more conductive pads extending through the set of two or more layers.

5. The multi-chip module of claim 1, further comprising two or more conductive vias disposed on either side of the first recess and configured to electrically isolate the first recess.

6. A multi-chip module comprising:
a first set of two or more layers including printed circuit boards (PCBs);
a second set of two or more layers including PCBs; and
a first recess formed between the first set and the second set.

7. The multi-chip module of claim 6, further comprising one or more solder bumps interconnecting the first set and the second set.

8. The multi-chip module of claim 6, further comprising a first fence attached to the first set and enclosing the first recess.

9. The multi-chip module of claim 8, further comprising a second fence attached to the second set and enclosing the first recess.

10. The multi-chip module of claim 8, wherein the first recess is configured to electrically isolate the first recess.

11. The multi-chip module of claim 6, further comprising a second recess formed between the first set and the second set.

12. The multi-chip module of claim 6, further comprising a third set of two or more layers including PCBs and a second recess formed between the second set and the third set.

13. A module comprising:
a first set of layers including printed circuit boards (PCBs);
a second set layers including PCBs; and
a first recess formed between the first set and the second set.

14. The module of claim 13, further comprising one or more solder bumps interconnecting the first set and the second set.

15. The module of claim 13, further comprising a first fence attached to the first set and enclosing the first recess.

16. The module of claim 15, further comprising a second fence attached to the second set and enclosing the first recess.

17. The module of claim 15, wherein the first recess is configured to electrically isolate the first recess.

18. The module of claim 13, further comprising a second recess formed between the first set and the second set.

19. The module of claim 13, further comprising a third set of two or more layers including PCBs and a second recess formed between the second set and the third set.

20. The module of claim 19, further comprising a second set of one or more solder bumps interconnecting the second set and the third set.
